(19) United States
(12) Patent Application Publication
(10) Pub. No.: US 2002/0030271 A1
(43) Pub. Date: Mar. 14, 2002

(54) Method and electronic database search engine for exposing the content of an electronic database

(76) Inventor: Pieter Jan Stappers, Delft (NL)

Correspondence Address: DARBY & DARBY P.C., 805 Third Avenue, New York, NY, 10022, US

(21) Appl. No.: 09/879,247

(22) Filed: Jun. 7, 2001

Related U.S. Application Data
(63) Continuation of application No. PCT/NL99/00697, filed on Nov. 15, 1999.

(30) Foreign Application Priority Data
Dec. 7, 1998 (NL) 1010741

(51) Int. Cl. H01L 23/34

(52) U.S. Cl. 257/726

(57) ABSTRACT

The present invention relates to an electronic database search engine comprising an electronic memory device suitable for storing and releasing elements from the database, a display unit, a user interface for selecting and displaying at least one element from the database on the display unit, and control means for controlling the user interface, which user interface allocates icons to the elements of the database, which icons are suitable for display on the display unit at mutual distances that depend on the elements' degree of dissimilarity, wherein the user interface at initial utilization displays at least some icons on the display unit. With the control means any arbitrary position can be selected on the display unit and, depending on the control means, the user interface displays or removes an icon that relates to an element of the database and of which degree of dissimilarity, in respect of the elements whose corresponding icons are displayed elsewhere on the display unit, corresponds with the distance taken up by the selected position in relation to the icons displayed elsewhere on the display unit.

The invention relates to a method and an electronic database search engine for disclosing an electronic database comprising an electronic memory device suitable for storing and releasing elements from the database, a display unit, a user interface for selecting and displaying at least one element from the database on the display unit, and control means for controlling the user interface, which user interface allocates icons to the elements of the database, which icons are suitable for display on the display unit at mutual distances that depend on the elements' degree of dissimilarity, wherein the user interface at initial utilization displays at least some icons on the display unit.

Such a method and device are disclosed in the article “Interactive Layout Mechanisms for Image Database Retrieval” by John MacCuish et al. dated Jan. 29, 1996, published in SPIE, vol. 2656, pp. 104-115. This article discloses an electronic database search engine, which uses a display unit showing objects from a database by means of icons or images in a two-dimensional plane. The mutual distance of the icons on the display area is a measure for the objects' dissimilarity. The electronic database search engine according to the article makes it possible by clicking on an image, to have the neighbouring images displayed on the display unit.

The disadvantage of the known device and method is that the spatial positioning of the elements is determined beforehand. All elements then have a fixed mutual positioning and orientation. This asks for compromises with respect to the visual presentation of the elements and their respective distances in relation to each other. Another disadvantage is that searching in the database is a rather slow process, which is partly due to the long computing time required by the known system, but more specifically to the rigid structures in which the elements are contained. This is especially true when the database requires a search strategy based on criteria that are subjective or that cannot readily, or not at all be objectified.

This is important since nowadays more and more collections and catalogues are indexed electronically. Examples of this are not only libraries and museum collections, but also catalogues of wines, films, music, paint colors, holiday destinations, and other products that are often assessed subjectively. State of the art search systems can help the user to (re)locate an exactly described element. However, it remains difficult for users to find the correct element in a collection of subjective criteria.

The state of the art solves the problem searching on a subjective criterion) by having the user select search terms from lists (menu selection, or indicating linguistic search profiles. This works well if the user searches an already known element, and he or she is familiar with the name or the desired attributes. In many situations, such as when searching new elements based on “taste” or intuition, the effectiveness of these search profiles is inadequate. Often laborious verbal dialogues in specialist jargon have to take place in order to try and obtain examples from the collection on the display. The dialogue requires that the user have knowledge of the definitions for the attributes stored with the elements (for example in the case of music: the genre, price, and performers).

It is the object of the invention to improve this. To this end the electronic database device and method according to the invention are characterized in that with the control means any arbitrary position can be selected on the display unit and in that, depending on the control means, the user interface displays or removes an icon that relates to an element of the database and of which the degree of dissimilarity, in respect of the elements whose corresponding icons are displayed elsewhere on the display unit, corresponds with the distance taken up by the selected position in relation to the icons displayed elsewhere on the display unit.

In this way it becomes possible to search in a database on the basis of criteria that are subjective or that cannot readily, or not at all, be objectified.

According to the invention an interactive manner of searching in the automized databank is provided, in which the user spatially indicates the relationship between his searched-for element and the selected examples from the collection. The dialogue may be graphical with a two- or three-dimensional display, in which a selection of elements is shown. The mutual distance between the elements displayed by means of icons demonstrates the similarity between the elements according to a criterion, which preferably is selected by the user. The user may search by asking for further information from selected icons, by removing icons, or by calling up a new element at positions between the icons. When searching in this manner, it is not necessary to know the attributed name. It is, however, possible to extend the method, in order to also support linguistic interaction.

An important advantage of the invention is that it allows rapid and direct search in a database comprising very different elements, without the necessity of going to the desired sub-collection via related characteristics or attributes of a preceding sub-collection.

After the addition or removal of icons, it is desirable according to the invention, for the user interface to adjust the mutual positioning of the icons on the display unit in concurrence with the mutual dissimilarity of the elements from the database such as to concur with the displayed icons, in order to optimize the display area usable on the display unit. Visually, such adjustments may take place both instantaneously and gradually. It should be noted, that the positioning of the displayed elements on the display unit is always scaled such that the possibility of reaching elements of greater dissimilarity remains open by calling up such an element at the periphery of the display unit.

Under certain search conditions it may be convenient that the user interface provides means for placing a selected icon permanently in the center of the display unit, while the remaining displayed icons are subsequently grouped around it.

In the method and device according to the invention, use may be made of a conventional graphical display unit, where the user, by means of a mouse, pen or by application of a touch screen, is able to “touch” positions on a display. At the beginning of the search, the display shows a small number of examples from the database. The elements shown on the display exhibit simulated, “self-organizing” behavior: they endeavor to position at mutual distances that correspond to the degree of dissimilarity of the attributes stored per element. When the user “clicks” on a position on the display, the user interface determines the distances between the click position and the positions of the elements already displayed. It then searches in the database for an element that exhibits the same degree of dissimilarity regarding said elements. That element then appears at the clicked-on position on the display. By clicking on the display closely to a particular element, the user searches a new element that closely resembles that particular element. By clicking on a far-removed portion, the user obtains a very dissimilar new element. When a new element has appeared, the user interface ensures that the elements adjust their mutual positions, thereby changing the visual configuration. The user can also remove elements by “dragging” them off the display. This creates more space on the display so that it is possible, as it were, to zoom in. It is also possible to call up further information for each displayed element, for example, by clicking on twice or by dragging it to a specific position on the display. This dialogue allows the user to navigate through the database in order to arrive at those elements, which best answer his search.

The invention optimally takes into account the capacity that users have of intuitively assessing the vague relationships between elements from the database, instead of using the less developed capacity of comparison to compare abstractly described ideas relating to said elements.

It may be desirable to add to the elements of the database characteristics that are involved when determining the elements' degree of dissimilarity, and to make the assessment of the dissimilarities between the various characteristics of the elements adjustable. This would provide the user with a simple manner to adjust the search to his requirements.

The electronic database search engine according to the invention can be applied in various ways. It would be conceivable to apply the device as taste searcher for consumers trying to make a selection from wines, holiday destinations, recipes, herbs, paint colors, music, films, and the like, so that the device with such a goal may find application in shops. The device according to the invention may also be used as remotely positioned databank, presented on the information supply market by publishers or other service providers.

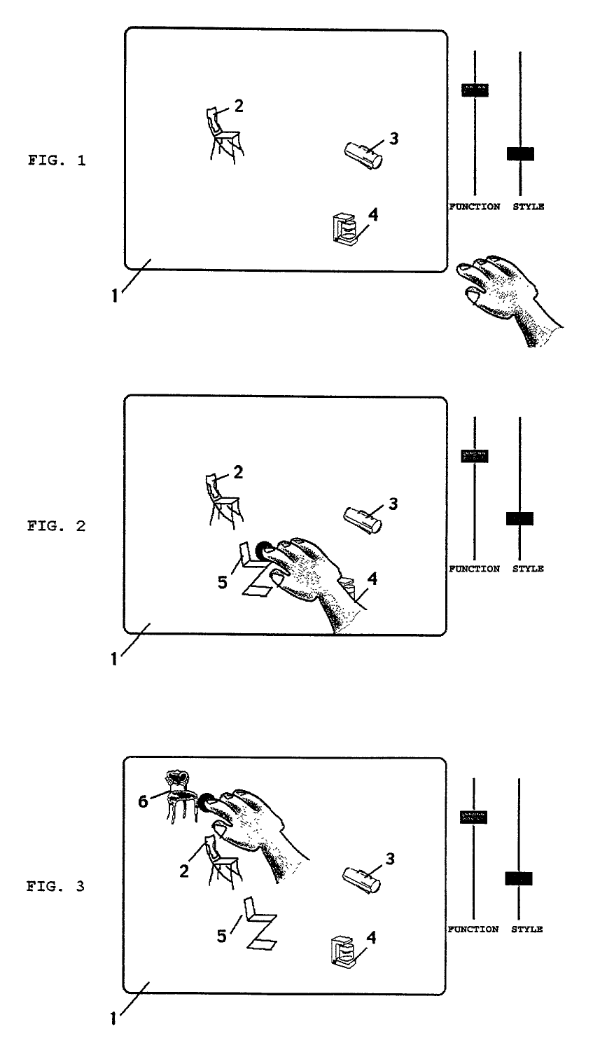

The invention will now be elucidated with reference to a drawing, which in the FIGS. 1 to 5 shows a non-limitative example of the application of the electronic database search engine according to the invention.

The FIGS. 1 to 5 schematically show a display such as will be observed by the user of a database search engine. The display unit 1 co-operates with an electronic memory device, suitable for storing and releasing elements from the database. To this end the display unit 1 is coupled to a user interface serving as intermediary between the display unit and the database, and serving for the selection and display of elements from the database on the display unit 1.

To this end the user interface allocates icons to elements from the database such as shown, for example, in FIG. 1, in the form of a chair 2, a vacuum cleaner 3, and a coffee maker 4. In the case illustrated, the database is formed by elements that are found in a domestic situation. Starting with the elements as shown in FIG. 1, a user can now touch any arbitrary location 5 on the display unit as shown in FIG. 2. At this location 5, an element from the database will then be shown by means of an icon relating to said element, whose degree of dissimilarity in relation to the elements 2, 3 and 4 already displayed on the display unit 1, corresponds with the distance assumed by the various elements and the touched area 5 on the display unit.

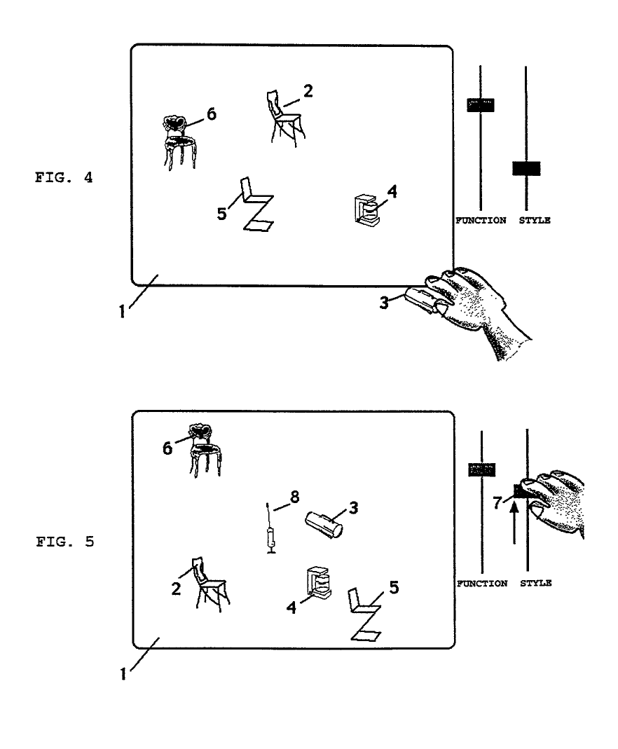

FIG. 3 shows a similar action, where in the left top corner of the display unit 1 an arbitrary area 6 is touched.

FIG. 4 shows that the icon 3, relating to the vacuum cleaner, is removed from the display after which, as is clearly shown in FIG. 4, the elements 2, 4, 5 and 6 remaining on the display unit 1, regroup with respect to their mutual positioning.

FIG. 5 indicates that the criterion, by which the degree of dissimilarity of the displayed elements is assessed, can be influenced. For example, in the case shown this involves a style aspect. By allowing this style aspect, which is controllable with a slide control 7, to carry more weight, style-related elements can be clustered on the display unit 1. This relates to the vacuum cleaner 3, the coffee maker 4, the chair 5, and the vacuum cleaner 8, shown in FIG. 5. The chairs 2 and 6 show obvious style differences, and are displayed at a greater distance from chain 5.

1. An electronic database search engine comprising an electronic memory device suitable for storing and releasing elements from the database, a display unit, a user interface for selecting and displaying at least one element from the database on the display unit, and control means for controlling the user interface, which user interface allocates icons to the elements of the database, which icons are suitable for display on the display unit at mutual distances that depend on the elements' degree of dissimilarity, wherein the user interface at initial utilization displays at least some icons on the display unit, wherein with the control means any arbitrary position can be selected on the display unit and in that, depending on the control means, the user interface displays or removes an icon that relates to an element of the database and of which the degree of dissimilarity, in respect of the elements whose corresponding icons are displayed elsewhere on the display unit, corresponds with the distance taken up by the selected position in relation to the icons displayed elsewhere on the display unit.

2. An electronic database search engine according to claim 1, wherein the user interface adjusts the mutual positioning of the icons on the display unit in concurrence with the mutual dissimilarity of the elements from the database such as to concur with the displayed icons, in order to optimize the display area usable on the display unit.

3. An electronic database search engine according to claim 1, wherein the user interface provides means for placing a selected icon permanently in the center of the display unit, while the remaining misplayed icons.

4. An electronic database search engine according to claim 1, wherein to the elements of the database characteristics are added that are involved in determining the elements' degree of dissimilarity, and that the assessment of the dissimilarities between the various characteristics of the elements is adjustable.

5. A method for disclosing an electronic database using an electronic database search engine, comprising an electronic memory device, a display unit and a user interface for selecting and displaying at least one element from the database on the display unit, and further control means for controlling the user interface, which user interface allocates icons to the elements of the database, and at initial utilization displays at least some icons on the display unit at mutual distances that depend on the degree of dissimilarity of the elements of the database that are represented by said icons, wherein with the control means any arbitrary position can be selected on the display unit and in that, depending on the control means, the user interface displays or removes an icon that relates to an element of the database and of which the degree of dissimilarity, in respect of the elements whose corresponding icons are displayed elsewhere on the display unit, corresponds with the distance taken up by the selected position in relation to the icons displayed elsewhere on the display unit.

6. A method according to claim 5, wherein the user interface adjusts the mutual positioning of the icons on the display unit in concurrence with the mutual dissimilarity of the elements from the database such as to concur with the displayed icons, in order to optimize the display area usable on the display unit.

7. A method according to claim 5, wherein the user interface provides means for placing a selected icon permanently in the center of the display unit, while the remaining displayed icons are subsequently grouped around it.

8. A method according to claim 5, wherein to the elements of the database characteristics are added that are involved when determining the elements' degree of dissimilarity, and that the assessment of the dissimilarities between the various characteristics of the elements is adjustable.
